(19) United States
(12) Patent Application Publication
(10) Pub. No.: US 2025/0224472 A1
(43) Pub. Date: Jul. 10, 2025

(54) RECONSTRUCTION APPARATUS, METHOD, AND MAGNETIC RESONANCE IMAGING APPARATUS

(71) Applicant: Canon Medical Systems Corporation, Otawara-shi (JP)

(72) Inventors: Hideaki KUTSUNA, Kawasaki (JP); Kensuke SHINODA, Otawara (JP)

(73) Assignee: Canon Medical Systems Corporation, Otawara-shi (JP)

(21) Appl. No.: 19/013,410

(22) Filed: Jan. 8, 2025

(30) Foreign Application Priority Data
Jan. 10, 2024 (JP) 2024-001982

(51) Int. Cl. G01R 33/56; G01R 33/24; G01R 33/561

(52) U.S. Cl. CPC G01R 33/5608; G01R 33/246; G01R 33/5615

(57) ABSTRACT

According to one embodiment, a reconstruction apparatus includes processing circuitry, the processing circuitry is configured to generate one or more sparse reconstructed images by performing image reconstruction on k-space data collected at each of a plurality of coils through under-sampling. The processing circuitry generates a first sensitivity map corresponding to each coil of the plurality of coils by using a first trained model. The processing circuitry performs a data consistency process for improving a degree of coincidence of data relating to the one or more sparse reconstructed images by using the first sensitivity map. The processing circuitry generates a full reconstructed image by performing a coil synthesis process using a second sensitivity map on the one or more sparse reconstructed images subjected to the data consistency process.

### CROSS-REFERENCE TO RELATED APPLICATIONS

This application is based upon and claims the benefit of priority from Japanese Patent Application No. 2024-001982, filed Jan. 10, 2024, the entire contents of which are incorporated herein by reference.

### FIELD

Embodiments described herein relate generally to a reconstruction apparatus, method, and magnetic resonance imaging apparatus.

### BACKGROUND

A method that combines a regularization process by a machine learning model, a data consistency process, and a coil synthesis process is known as an image reconstruction method for generating an MR (magnetic resonance) image. Normally, the same sensitivity map is used when the data consistency process and the coil synthesis process are performed. There is also a method of estimating a sensitivity map using a machine learning model as position processing for obtaining a sensitivity map.

If the above methods are combined, the process result of the coil synthesis process greatly affects the training, causing the training of a model to proceed so as to be similar to a sensitivity map as correct data. Thus, the training of a machine learning model for estimating a sensitivity map is not effectively performed, and the image quality of a reconstructed image is not as high as expected.

### BRIEF DESCRIPTION OF THE DRAWINGS

FIG. 1 is a block diagram showing a reconstruction apparatus according to a first embodiment.

FIG. 2 is a flowchart illustrating a reconstruction process performed by the reconstruction apparatus according to the first embodiment.

FIG. 3 is a conceptual diagram illustrating a first example of an inference process performed by the reconstruction apparatus according to the first embodiment.

FIG. 4 is a conceptual diagram illustrating a second example of an inference process performed by the reconstruction apparatus according to the first embodiment.

FIG. 5 is a block diagram showing a reconstruction apparatus according to a second embodiment.

FIG. 6 is a flowchart illustrating a training process performed by the reconstruction apparatus according to the second embodiment.

FIG. 7 is a conceptual diagram illustrating a training process performed by the reconstruction apparatus according to the second embodiment.

FIG. 8 is a conceptual diagram illustrating another example of a training process performed by the reconstruction apparatus according to the second embodiment.

FIG. 9 is a conceptual diagram illustrating an inference process performed by a reconstruction apparatus according to a third embodiment.

FIG. 10 is a conceptual diagram illustrating another example of a training process performed by the reconstruction apparatus according to the third embodiment.

FIG. 11 is a block diagram showing a magnetic resonance imaging apparatus according to a fourth embodiment.

### DETAILED DESCRIPTION

In general, according to an embodiment, a reconstruction apparatus includes processing circuitry, the processing circuitry is configured to generate one or more sparse reconstructed images by performing image reconstruction on k-space data collected at each of a plurality of coils through under-sampling. The processing circuitry generates a first sensitivity map corresponding to each coil of the plurality of coils by using a first trained model. The processing circuitry performs a data consistency process for improving a degree of coincidence of data relating to the one or more sparse reconstructed images by using the first sensitivity map. The processing circuitry generates a full reconstructed image by performing a coil synthesis process using a second sensitivity map on the one or more sparse reconstructed images subjected to the data consistency process.

Hereinafter, embodiments of a reconstruction apparatus, method, program, and magnetic resonance imaging apparatus will be described in detail with reference to the accompanying drawings. In the embodiments described below, elements assigned the same reference symbols are assumed to perform the same operations, and redundant descriptions thereof will be omitted as appropriate. An embodiment will be described below with reference to the accompanying drawings.

### First Embodiment

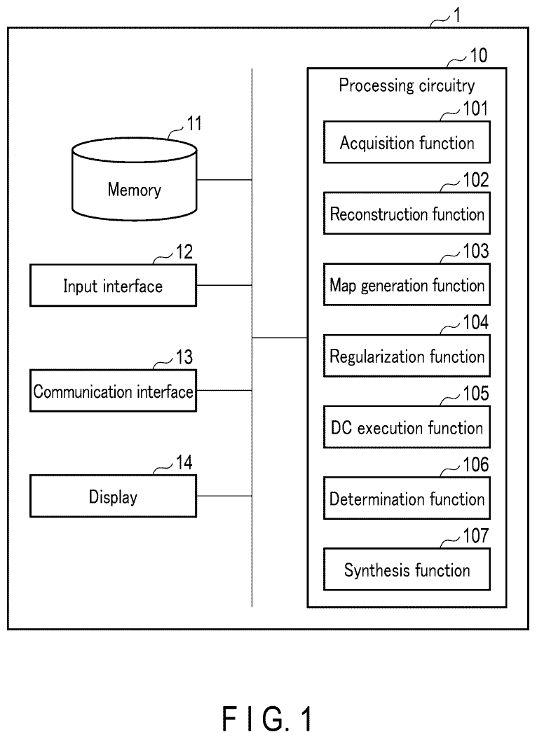

A reconstruction apparatus according to a first embodiment will be described with reference to the block diagram of FIG. 1.

A reconstruction apparatus 1 shown in FIG. 1 is a computer that has processing circuitry 10, a memory 11, an input interface 12, a communication interface 13, and a display 14.

The processing circuitry 10 has a processor such as a CPU, as a hardware resource. For example, the processing circuitry 10 executes various programs to implement an acquisition function 101, a reconstruction function 102, a map generation function 103, a regularization function 104, a DC (data consistency) execution function 105, a determination function 106, and a synthesis function 107.

With the acquisition function 101, the processing circuitry 10 acquires k-space data collected through under-sampling at each of the coils of a magnetic resonance imaging apparatus. The k-space data collected through under-sampling is not limited to k-space data regularly sparsely-acquired as in parallel imaging, and may be randomly sampled k-space data as in compressed sensing, k-space data collected by a half-Fourier method, or k-space data in which the high-frequency part is not collected and only the low-frequency component is collected for super-resolution.

With the reconstruction function 102, the processing circuitry 10 performs image reconstruction on the acquired k-space data to generate one or more sparse reconstructed images. The sparse reconstructed image is an under-sampled reconstructed image based on the k-space data that corresponds to each coil. Since the sparse reconstructed image has an insufficient number of samples due to under-sampling, it becomes an image with aliasing.

With the map generation function 103, the processing circuitry 10 generates a first sensitivity map corresponding to each coil by using a first trained model.

With the regularization function 104, the processing circuitry 10 performs a regularization process on one or more sparse reconstructed images by using a second trained model. The regularization process is a process of removing the aliasing of the sparse reconstructed image.

With the DC execution function 105, the processing circuitry 10 performs a data consistency process using a first sensitivity map. The data consistency process is a process for improving the degree of coincidence of the data relating to one or more sparse reconstructed images.

With the determination function 106, the processing circuitry 10 determines whether or not the regularization process and the data consistency process are repeatedly performed a necessary number of times.

With the synthesis function 107, the processing circuitry 10 performs a coil synthesis process using a second sensitivity map on the one or more sparse reconstructed images subjected to the data consistency process. As a result of the coil synthesis process, a full reconstructed image, which is an image equivalent to a reconstructed image generated from fully sampled k-space data, is generated.

The memory 11 is a storage device such as a hard disk drive (HDD), solid state drive (SSD), or integrated circuit storage device for storing various kinds of information. The memory 11 may be, for example, a driver that reads and writes various kinds of information from and to a portable storage medium such as a CD-ROM drive, a DVD drive, or a flash memory. For example, the memory 11 stores medical data including reconstructed images collected in the past, a control program, and a trained model.

The input interface 12 includes an input device that receives various commands from a user. Examples of the input device that can be used include a keyboard, a mouse, various switches, a touch screen, and a touch pad. The input device is not limited to a device equipped with physical operational parts such as a mouse and a keyboard. Examples of the input interface 12 also include electric signal processing circuitry that receives an electric signal corresponding to an input operation through an external input device provided separately from the reconstruction apparatus and outputs the received electric signal to various types of circuitry. The input interface 12 may also be a voice recognition device that receives voice signals via a microphone and converts the voice signals into command signals.

The communication interface 13 is an interface that connects the reconstruction apparatus with a workstation, a picture archiving and communication system (PACS), a hospital information system (HIS), a radiology information system (RIS), etc., via a local area network (LAN), etc. The communication interface 13 transmits and receives various kinds of information to and from the connected workstation, PACS, HIS, and RIS.

The display 14 displays various kinds of information. For example, a CRT display, a liquid crystal display, an organic EL display, an LED display, a plasma display, or any other display known in the relevant technical field can be suitably used as the display 14.

Although FIG. 1 shows a configuration of including the display 14 in the reconstruction apparatus 1, an external display device such as a monitor may be used as the display so that the display 14 need not be included in the reconstruction apparatus 1.

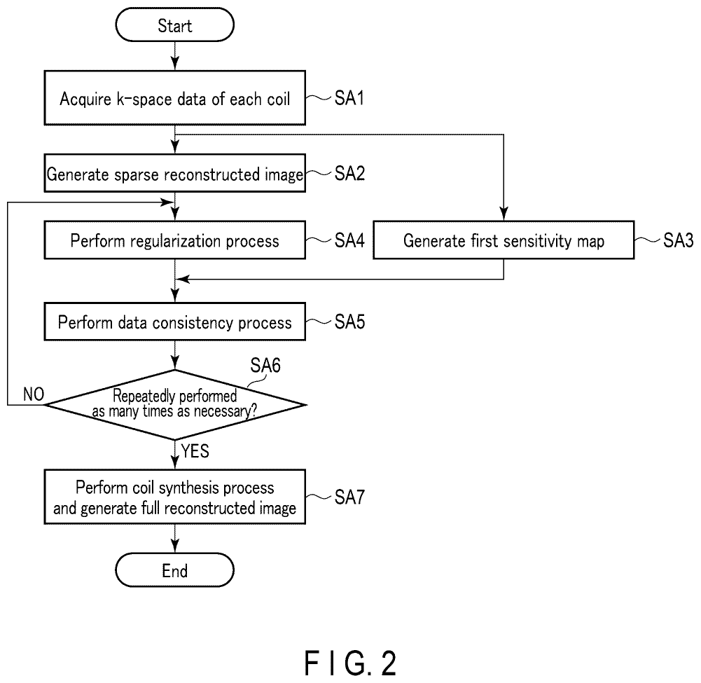

Next, the reconstruction process (inference process) of the reconstruction apparatus 1 according to the first embodiment will be explained with reference to the flowchart of FIG. 2.

In step SA1, with the acquisition function 101, the processing circuitry 10 acquires k-space data collected through under-sampling at each of the coils of a magnetic resonance imaging apparatus. For example, k-space data based on a thinned and collected MR signal that is obtained by a parallel imaging method may be acquired.

In step SA2, with the reconstruction function

102, the processing circuitry 10 performs image reconstruction on the k-space data of each coil to generate one or more sparse reconstructed images corresponding to each coil.

In step SA3, with the map generation function 103, the processing circuitry 10 generates a first sensitivity map corresponding to each coil by using a first trained model.

In step SA4, with the regularization function 104, the processing circuitry 10 performs a regularization process on one or more sparse reconstructed images by using a second trained model.

In step SA5, with the DC execution function 105, the processing circuitry 10 performs a data consistency process on one or more regularized sparse reconstructed images by using a first sensitivity map. For example, a process of reducing an error between the k-space data as input data and the regularized sparse reconstructed image(s) obtained in step SA4 may be performed as the data consistency process. For example, optimization that reduces a square error between k-space data obtained by subjecting the regularized sparse reconstructed images to Fourier transform and the k-space data of step SA1 may be performed.

In step SA6, with the determination function 106, the processing circuitry 10 determines whether or not the regularization process and the data consistency process as one set of processes are repeatedly performed as many times as necessary. For example, the number of repetitions may be set in advance as the number of times that the set of processes needs to be performed, and it may be determined that the set of processes has been repeatedly performed as many times as necessary if the number of repetitions of the set of processes reaches a predetermined number of times. Alternatively, it may be determined that the set of processes has been repeatedly performed as many times as necessary if the square error in the data consistency process is equal to or below a threshold.

If the regularization process and the data consistency process are repeatedly performed as many times as necessary, the process proceeds to step SA7, and if not, the process returns to step SA4 and repeats step SA4 and step SA5.

In step SA7, with the synthesis function 107, the processing circuitry 10 performs a coil synthesis process using a second sensitivity map on one or more sparse reconstructed images subjected to the data consistency process, and generates a full reconstructed image. The second sensitivity map may be a sensitivity map (e.g., ESPIRiT) obtained by using the k-space data acquired in step SA1, a sensitivity map of a coil acquired when prescanning such as positioning scanning is performed, or a sensitivity map based on k-space data relating to main scanning and collected at a different timing from the timing of the scanning performed to acquire the k-space data.

Alternatively, the second sensitivity map may be generated using a trained model. The second sensitivity map may be generated by, for example, inputting k-space data to a trained model that is a model trained to output a sensitivity map after k-space data is input thereto.

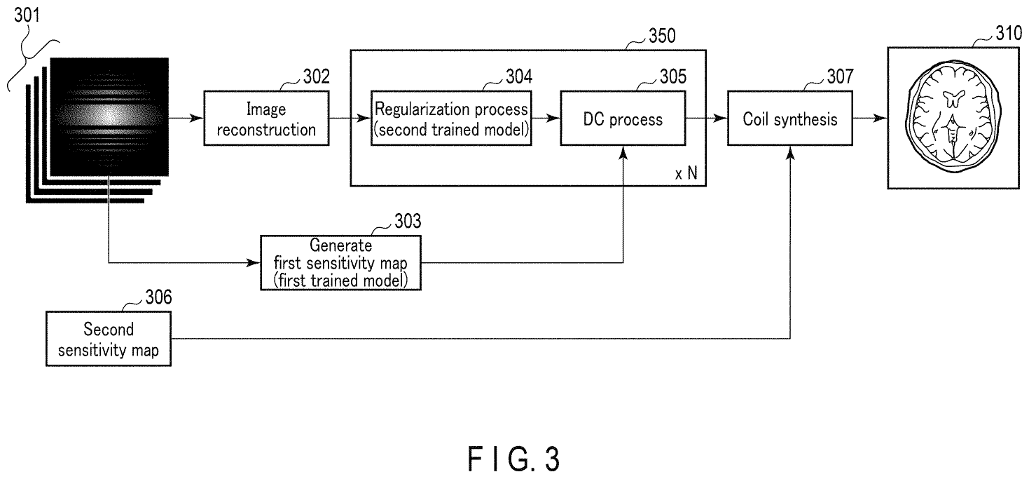

Next, a first example of an inference process performed by the reconstruction apparatus according to the first embodiment will be described with reference to the conceptual diagram of FIG. 3.

In FIG. 3, an image reconstruction process 302 is performed on k-space data 301 acquired at a plurality of coils through under-sampling, and a plurality of sparse reconstructed images are obtained. On the other hand, a first sensitivity map generation process 303 is performed on each coil at which the k-space data 301 is acquired using a first trained model, and a first sensitivity map is generated. For example, a so-called SME (sensitivity map estimation) module may be used as the first trained model. As the process by the SME module, a process is performed, for example, in which a part of the k-space data 301 other than the central data in the k-space is masked, that is, in the case of a GRAPPA (Generalized Auto calibrating Partially Parallel Acquisition) method, a part of the k-space data 301 other than ACS (autocalibration signal) data is masked, an inverse Fourier transform is performed to apply a convolutional neural network to each image, and the sensitivity map of each coil is regularized.

The second trained model is applied to the sparse reconstructed image after the image reconstruction process 302, and a regularization process 304 is performed. Thereafter, a data consistency process 305 (also referred to as “a DC process 305”) is performed on the plurality of sparse reconstructed images after the regularization process 304. The regularization process and the DC process as a set 350 of processes is repeatedly performed an N number of times (N being a natural number of one or more).

Thereafter, the second sensitivity map 306 is used to perform coil synthesis 307 on the plurality of sparse reconstructed images for which the set 350 of processes is completed, and a full reconstructed image 310 is generated.

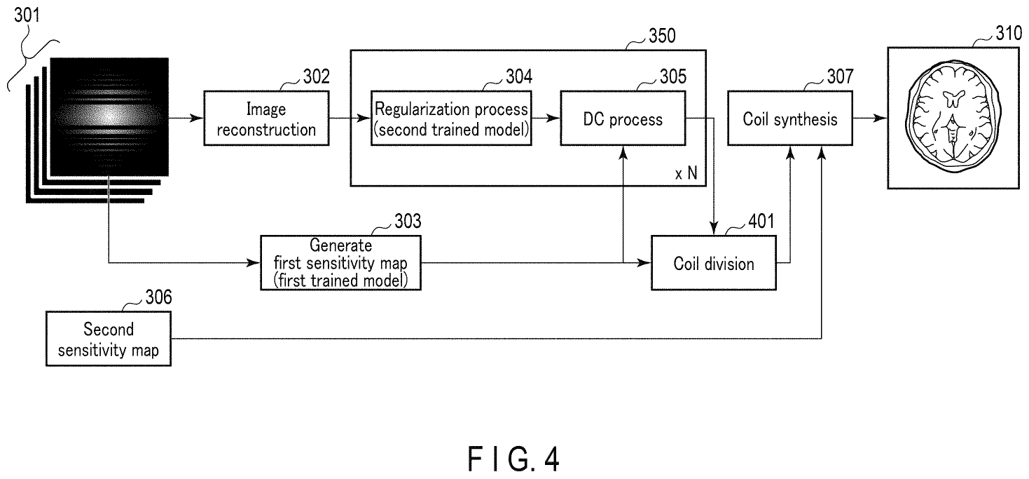

Next, a first example of an inference process performed by the reconstruction apparatus according to the first embodiment will be described with reference to the conceptual diagram of FIG. 4.

FIG. 4 assumes a case where there is only one sparse reconstructed image, not a plurality of sparse reconstructed images, after the image reconstruction process. That is, an image reconstruction process 302 is performed on k-space data 301 acquired at a plurality of coils through under-sampling, and a single sparse reconstructed image is obtained. For example, in the case of a CG-SENSE (conjugate gradient-sensitivity encoding)-type DC process, a single image is processed; thus, a single sparse reconstructed image may be processed.

The difference from FIG. 3 is that the processing circuitry 10, for example, performs coil division 401 after the DC process 305 by implementing the synthesis function 107. The coil division 401 generates a plurality of sparse reconstructed images from a single sparse reconstructed image by using a plurality of first sensitivity maps corresponding to a plurality of coils. Thereafter, the coil synthesis 307 is performed, and a full reconstructed image 310 is generated as in the case of FIG. 3.

The following description explains, as an example, a case where a plurality of sparse reconstructed images are generated after an image reconstruction process; however, the same process may be performed when a single sparse reconstructed image is generated after an image reconstruction process. That is, a process relating to coil division may be performed before the coil synthesis, as shown in FIG. 4.

According to the first embodiment described above, an image is reconstructed from k-space data collected at each coil through under-sampling, and a plurality of sparse reconstructed images are generated. A first sensitivity map corresponding to each coil is generated using a first trained model, and a data consistency process relating to a sparse reconstructed image is performed using the first sensitivity map. A coil synthesis process using a second sensitivity map is performed on each sparse reconstructed image subjected to the data consistency process, and a full reconstructed image is generated. Thus, a sensitivity map specialized for the data consistency process can be utilized, and the image quality of a full reconstructed image, that is, the image quality of a reconstructed image finally obtained, can be improved.

### Second Embodiment

In the first embodiment, a machine learning model included in the reconstruction apparatus 1 is assumed to be a model that has already been trained, and a second embodiment differs from the first embodiment in that the reconstruction apparatus 1 has a training function for training a model.

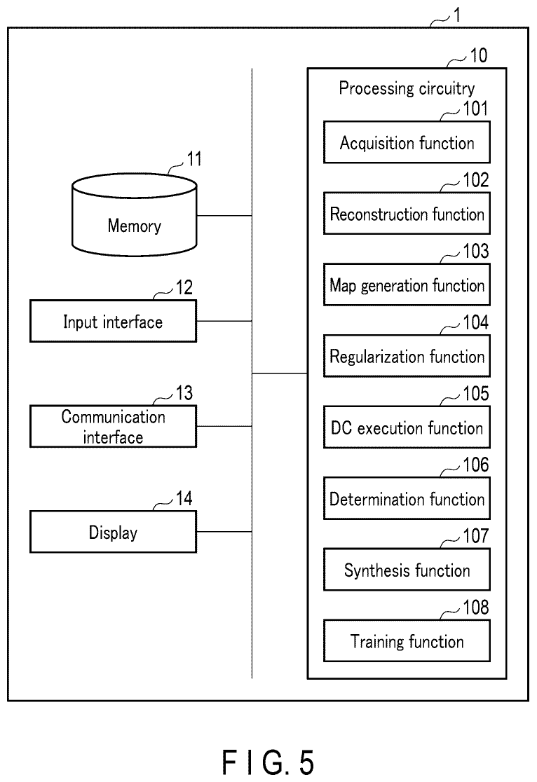

A reconstruction apparatus 1 according to the second embodiment will be described with reference to the block diagram of FIG. 5.

The reconstruction apparatus 1 according to the second embodiment includes processing circuitry 10, a memory 11, an input interface 12, a communication interface 13, and a display 14. The processing circuitry 10 includes a training function 108 in addition to the configuration of the first embodiment.

The training function 108 trains a machine learning model used in the regularization function 104 and a machine learning model used in the DC execution function 105.

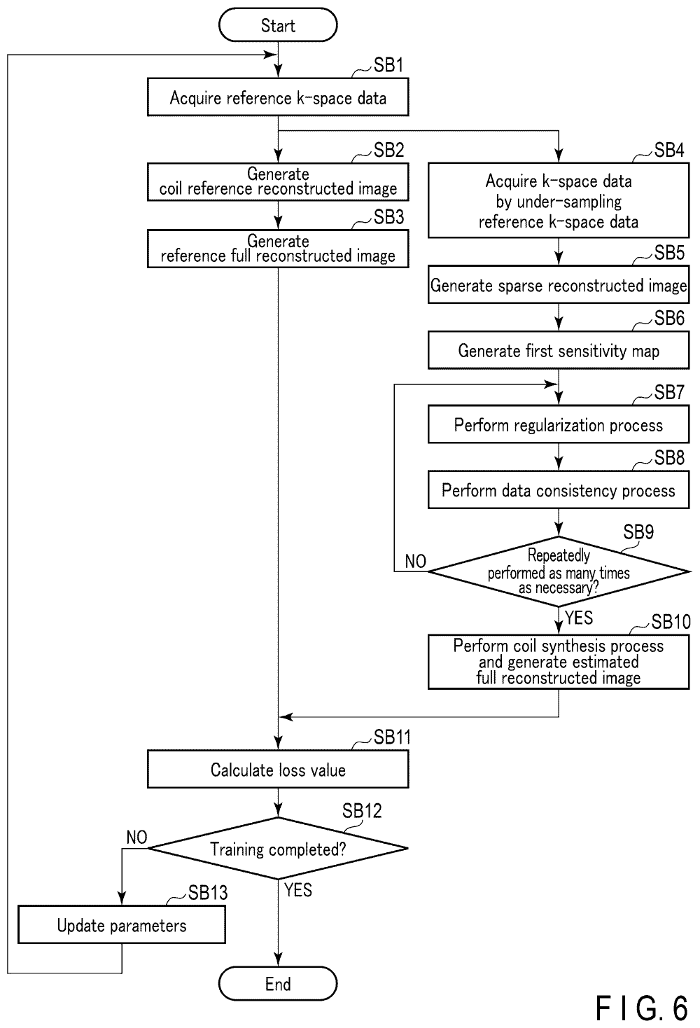

Next, a training process performed by the reconstruction apparatus 1 according to the second embodiment will be explained with reference to the flowchart of FIG. 6.

In step SB1, with the acquisition function 101, the processing circuitry 10 collects reference k-space data, which is k-space data of full sampling as correct data.

In step SB2, with the reconstruction function 102, the processing circuitry 10 performs an image reconstruction process on the reference k-space data and generates a coil reference reconstructed image, which is a reconstructed image of each coil.

In step SB3, with the synthesis function 107, the processing circuitry 10 performs a coil synthesis process on the coil reference reconstructed image by using a sensitivity map of each coil generated from the reference k-space data, and generates a reference full reconstructed image.

In step SB4, with the acquisition function 101, the processing circuitry 10 under-samples the reference k-space data used in step SB1 and acquires under-sampled k-space data of each coil as input data of training data. The under-sampled k-space data may be generated by, for example, thinning out the reference k-space data in such a manner as to sample one row every four rows along a ky direction or a kx direction. In the case of adopting a method other than a parallel imaging method as under-sampling, the reference k-space data may be processed so as to yield data under-sampled from the reference k-space data. If a half Fourier method is adopted as under-sampling, for example, k-space data relating to a half+α region of a k-space may be acquired.

In step SB5, with the reconstruction function 102, the processing circuitry 10 subjects the under-sampled k-space data to an image reconstruction process, and generates a sparse reconstructed image of each coil.

In step SB6, with the map generation function 103, the processing circuitry 10 generates a first sensitivity map corresponding to each of the plurality of coils by using a first model for generating a sensitivity map, which is a training target. The first model may be a general machine learning model such as a convolutional neural network, an autoencoder, or the like.

In step SB7, with the regularization function 104, the processing circuitry 10 performs a regularization process on the sparse reconstructed image by using a second model for performing a regularization process, which is a training target. The second model may also be a general machine learning model, as in the case of the first model.

In step SB8, with the DC execution function 105, the processing circuitry 10 performs a data consistency process on the regularized sparse reconstructed image by using the first sensitivity map generated in step SB6.

In step SB9, with the determination function 106, the processing circuitry 10 determines whether or not the regularization process and the data consistency process as a set are repeatedly performed as many times as necessary. The same method as in step SA6 may be used to determine whether or not the regularization process and the data consistency process as a set are repeatedly performed. If the set of processes are repeatedly performed as many times as necessary, the process proceeds to step SB10, and if not, the process returns to step SB7 and repeats the same steps.

In step SB10, with the synthesis function 107, the processing circuitry 10 performs a coil synthesis process using a sensitivity map on each sparse reconstructed image subjected to the data consistency process, and generates an estimated full reconstructed image. The sensitivity map used herein may be the sensitivity map used in step SB3.

In step SB11, with the training function 108, the processing circuitry 10 calculates a value of loss between the reference full reconstructed image and the estimated full reconstructed image by using a loss function. The loss function used may be a general loss function used in machine learning such as MSE (mean squared error), binary cross entropy, etc.

In step SB12, with the training function 108, the processing circuitry 10 determines whether the training is completed or not based on the value of loss calculated in step SB10. Specifically, if the value of loss is equal to or below a threshold and the value of loss converges, for example, it may be determined that the training is completed. Alternatively, if the training is repeatedly performed for a predetermined number of epochs, it may be determined that the training is completed. That is, a general method of determining completion of training in machine learning may be employed. If the training is not completed, the process proceeds to step SB13. On the other hand, if the training is completed, a first trained model and a second trained model are determined, and the process is completed.

In step SB13, the parameters (a weight and a bias) of the first model and the second model are updated, and the process returns to step SB1 to repeat the same steps for new reference k-space data.

In the example shown in FIG. 6, under-sampled k-space data is acquired after a reference full reconstructed image is generated; however, the embodiment is not limited thereto. The process of generating a reference full reconstructed image and the process of generating an estimated full reconstructed image may be performed in parallel. That is, the process of steps SB2 to SB3 and the process of steps SB4 to SB10 may be performed in parallel.

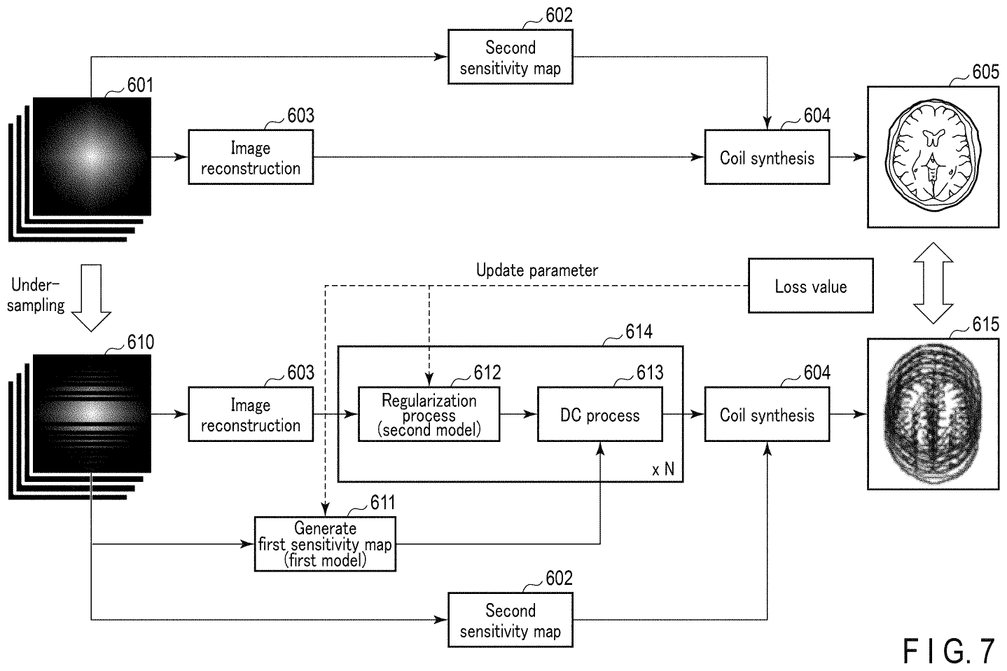

Next, a training process performed by the reconstruction apparatus according to the second embodiment will be explained with reference to the conceptual diagram of FIG. 7.

A second sensitivity map 602 of each coil is generated from reference k-space data 601. In this instance, the second sensitivity map 602 is generated from each of four pieces of reference k-space data 601. An image reconstruction process 603 and a coil synthesis process 604 using the second sensitivity map 602 are performed on the reference k-space data 601, whereby a reference full reconstructed image 605 as correct data is generated.

On the other hand, under-sampled k-space data 610 is generated by subjecting the reference k-space data 601 to a process of thinning out or masking a row along a kx direction or a ky direction. A first sensitivity map generation process 611 is performed on the k-space data 610. Specifically, the k-space data 610 is input to a first model, and a first sensitivity map is output. The k-space data 610 is subjected to the image reconstruction process 603, and a sparse reconstructed image is generated. When the sparse reconstructed image is input to a second model, a regularization process 612 is performed, after which a DC process 613 is performed. A set 614 of the regularization process 612 and the DC process 613 by the second model is repeatedly performed (N times). Thereafter, the coil synthesis process 604 is performed using the second sensitivity map 602, whereby an estimated full reconstructed image 615 is generated.

The reference full reconstructed image 605 and the estimated full reconstructed image 615 are compared with each other, the training situation is determined based on a value of loss calculated from a loss function, and the parameters of the first model and the second model are updated until it is determined that the training is completed.

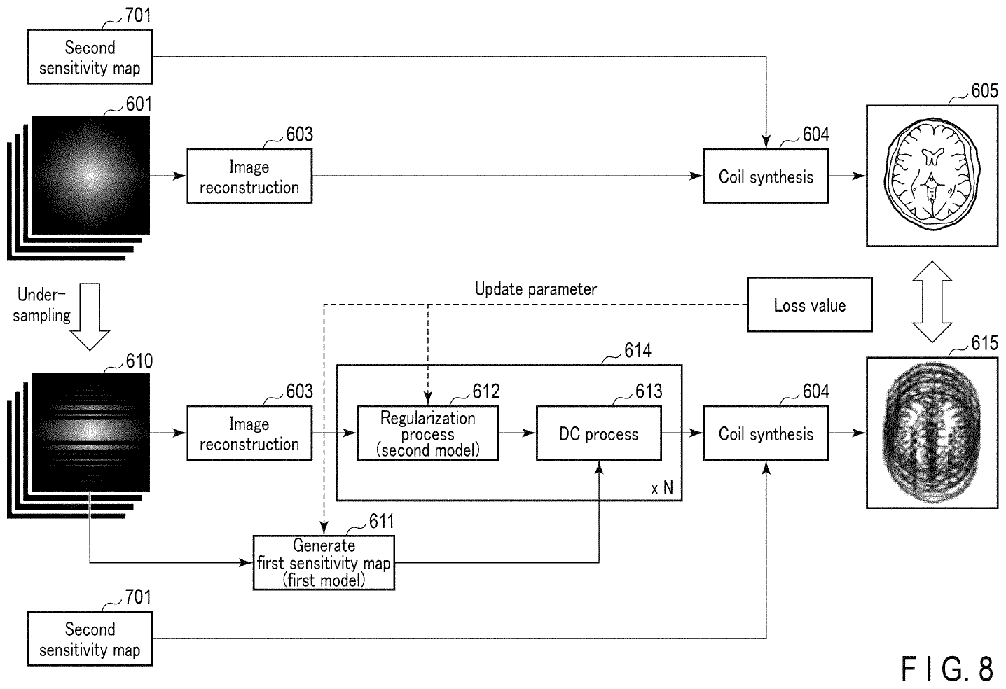

Next, another example of a training process performed by the reconstruction apparatus 1 according to the second embodiment will be explained with reference to the conceptual diagram of FIG. 8.

While FIG. 7 shows an example in which the second sensitivity map 602 is generated from the reference k-space data 601 or the under-sampled k-space data 610, FIG. 8 shows an example in which a second sensitivity map 701 obtained through different scanning is used. For example, the second sensitivity map 701 may be generated through reference scanning in the parallel imaging method, generated using a neural network, or generated by any means, provided that a sensitivity map corresponding to the k-space data 610 can be generated.

It is not necessary to use the same sensitivity map as the second sensitivity map when performing the training of a first model 611 and a second model 612 and when performing an inference such as the one shown in the first embodiment; different sensitivity maps may be used as the second sensitivity map. For example, the second sensitivity map 602 (e.g., ESPIRiT) may be used when the training of the first model 611 and the second model 612 according to the second embodiment are performed, and the second sensitivity map 701 (e.g., a sensitivity map generated through reference scanning in the parallel imaging method) may be used when the inference according to the first embodiment is performed.

According to the second embodiment described above, the first model for estimating the sensitivity map and the second model for performing the regularization process are trained simultaneously, and, in the coil synthesis process, the first model and the second model are trained using the second sensitivity map different from the first sensitivity map output from the first model. Thus, in the training of the first model, it is possible to proceed with training without making an estimation close to a sensitivity map of correct data as a reference, as compared to the case where the first sensitivity map is also used in the coil synthesis process, allowing for generation of a trained model that improves the image quality of an estimated reconstructed image.

### Third Embodiment

A third embodiment differs from the embodiments described above in that a water-fat separation method such as a DIXON method is applied to a reconstruction process in multi-echo (multi-contrast) imaging.

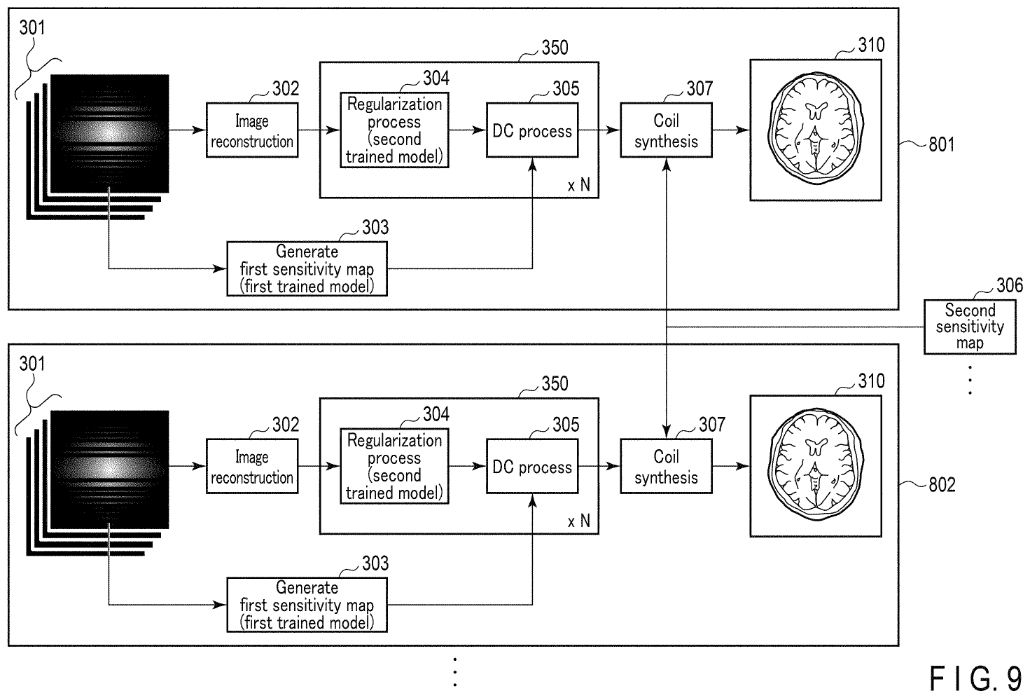

An inference process performed by the reconstruction apparatus 1 according to the third embodiment will be explained with reference to the conceptual diagram of FIG. 9.

FIG. 9 shows a process performed on a first echo 801 by the reconstruction apparatus 1 and a subsequent process performed on a second echo 802 by the reconstruction apparatus 1. Herein, a sensitivity map common to the first echo 801 and the second echo 802 is used as the second sensitivity map 306 used in the coil synthesis process 307.

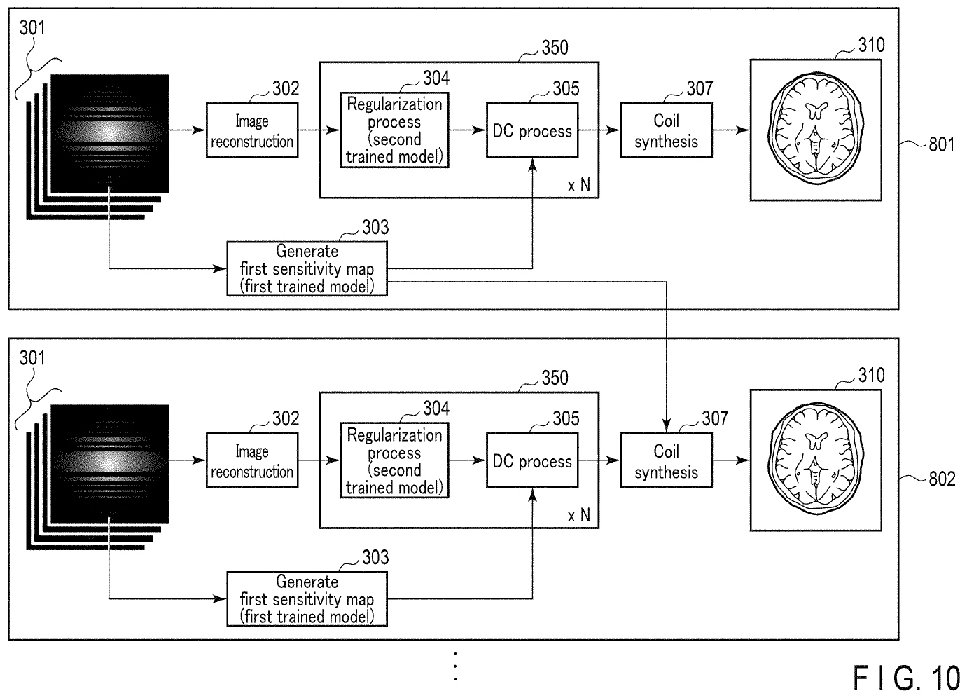

Next, another example of an inference process performed by the reconstruction apparatus 1 according to the third embodiment will be explained with reference to the conceptual diagram of FIG. 10.

In FIG. 10, a first sensitivity map output from the first trained model obtained in another echo is used as a second sensitivity map in the echo to be processed.

Specifically, in the example shown in FIG. 10, a first sensitivity map output from the first trained model in the first sensitivity map generation process 303 performed on the first echo 801 may be used for the coil synthesis process 307 as the second sensitivity map of the process performed on the second echo 802.

The embodiment is not limited to using a first sensitivity map preceding in time series, and may use a first sensitivity map obtained by the process performed on the second echo 802 for the coil synthesis process 307 as the second sensitivity map of the process performed on the first echo 801.

This instance explains two echoes, the first echo 801 and the second echo 802; however, in the case of three or more echoes as well, a first sensitivity map in another echo can likewise be employed as the second sensitivity map of the echo to be processed.

According to the third embodiment described above, a common second sensitivity map is used in multi-echo imaging. Alternatively, a first sensitivity map generated in a process relating to another echo is used as the second sensitivity map for the echo to be processed. Thus, the image quality of each full reconstructed image generated in multi-echo imaging can be improved.

### Fourth Embodiment

A fourth embodiment assumes a magnetic resonance imaging apparatus equipped with a reconstruction apparatus.

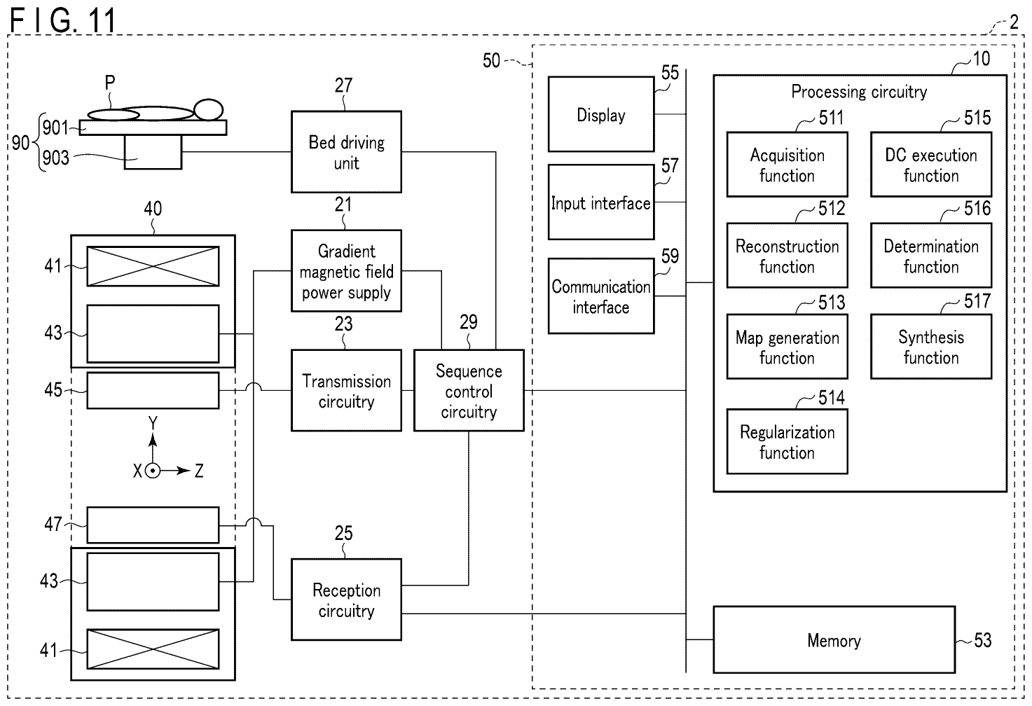

FIG. 11 is a block diagram showing an example of a configuration of a magnetic resonance imaging apparatus 2 according to this embodiment. As shown in FIG. 11, the magnetic resonance imaging apparatus 2 includes a gantry 40, a bed 90, a gradient magnetic field power supply 21, transmission circuitry 23, reception circuitry 25, a bed driving unit 27, sequence control circuitry 29, and a host computer 50.

The gantry 40 includes a static magnetic field magnet 41 and a gradient magnetic field coil 43. The static magnetic field magnet 41 and the gradient magnetic field coil 43 are accommodated in a housing of the gantry 40. The housing of the gantry 40 is formed with a bore having a hollow shape. A transmitter coil 45 and a receiver coil 47 are arranged in the bore of the gantry 40.

The static magnetic field magnet 41 has a hollow, approximately cylindrical shape, and generates a static magnetic field thereinside. Examples of the static magnetic field magnet 41 that are used include a permanent magnet, a superconducting magnet, or a normal conducting magnet. Here, a central axis of the static magnetic field magnet 41 is defined as a Z-axis, an axis vertically orthogonal to the Z-axis is defined as a Y-axis, and an axis horizontally orthogonal to the Z-axis is defined as an X-axis. The X-axis, Y-axis, and Z-axis constitute an orthogonal three-dimensional coordinate system.

The gradient magnetic field coil 43 is a coil unit attached to the inside of the static magnetic field magnet 41 and formed in a hollow, approximately cylindrical shape. The gradient magnetic field coil 43 receives a supply of a current from the gradient magnetic field power supply 21 to generate a gradient magnetic field. Specifically, the gradient magnetic field coil 43 includes three coils corresponding to the X-axis, the-Y axis, and the-Z axis, which are orthogonal to each other. The three coils form gradient magnetic fields in which the magnetic field intensity varies along the X-axis, the Y-axis, and the Z-axis, respectively. The gradient magnetic fields along the X-axis, the Y-axis, and the Z-axis are combined to form, in desired directions, a frequency encoding gradient magnetic field Gr, a phase encoding gradient magnetic field Gp, and a slice selection gradient magnetic field Gs, which are orthogonal to each other. The frequency encoding gradient magnetic field Gr is used to change the frequency of a magnetic resonance signal (MR signal) in accordance with a spatial position. The phase encoding gradient magnetic field Gp is used to change the phase of an MR signal in accordance with a spatial position. The slice selection gradient magnetic field Gs is used to discretionarily determine an imaging cross-section (slice). The following description is based on the premise that the gradient direction of the frequency encoding gradient magnetic field Gr aligns with the X-axis, the gradient direction of the phase encoding gradient magnetic field Gp aligns with the Y-axis, and the gradient direction of the slice selection gradient magnetic field Gs aligns with the Z-axis.

The gradient magnetic field power supply 21 supplies a current to the gradient magnetic field coil 43 in accordance with a sequence control signal from the sequence control circuitry 29. Through the supply of a current to the gradient magnetic field coil 43, the gradient magnetic field power supply 21 causes the gradient magnetic field coil 43 to generate gradient magnetic fields along the X-axis, the Y-axis, and the Z-axis. The gradient magnetic fields are superimposed on a static magnetic field formed by the static magnetic field magnet 41 and applied to a subject P.

The transmitter coil 45 is, for example, arranged inside the gradient magnetic field coil 43, and generates a high-frequency pulse (hereinafter, referred to as an “RF pulse”) upon receiving a current supplied from the transmission circuitry 23.

The transmission circuitry 23 supplies a current to the transmitter coil 45 in order to apply an RF pulse for exciting a target proton existing in the subject P to the subject P via the transmitter coil 45. The RF pulse oscillates at a resonance frequency specific to the target proton to excite the target proton. An MR signal is generated from the excited target proton and is detected by the receiver coil 47. The transmitter coil 45 is, for example, a whole-body coil (WB coil). The whole-body coil may be used as a transmitter-receiver coil.

In response to an action of the RF pulse, the receiver coil 47 receives the MR signal generated from the target proton in the subject P. The receiver coil 47 has a plurality of receiver coil elements capable of receiving an MR signal. The received MR signal is supplied to the reception circuitry 25 either wirelessly or via a wire. Although not shown in FIG. 11, the receiver coil 47 has a plurality of reception channels arranged in parallel. Each reception channel has a receiver coil element for receiving an MR signal, an amplifier for amplifying the MR signal, etc. An MR signal is output from each reception channel. The total number of reception channels may be equal to, larger than, or smaller than the total number of receiver coil elements.

The reception circuitry 25 receives an MR signal generated from the excited target proton via the receiver coil 47. The reception circuitry 25 processes the received MR signal to generate a digital MR signal. The digital MR signal can be expressed by a k-space defined by spatial frequency. Thus, digital MR signals are referred to as “k-space data”.

The transmitter coil 45 and the receiver coil 47 described above are mere examples. Instead of the transmitter coil 45 and the receiver coil 47, a transmitter-receiver coil having both a transmitting function and a receiving function may be used. Also, the transmitter coil 45, the receiver coil 47, and a transmitter-receiver coil may be combined.

The bed 90 is installed adjacently to the gantry 40. The bed 90 has a top board 901 and a base 903. The subject P is placed on the top board 901. The base 903 supports the top board 901 slidably along each of the X-axis, the Y-axis, and the Z-axis. The bed driving unit 27 is accommodated in the base 903. The bed driving unit 27 moves the top board 901 under the control of the sequence control circuitry 29. The bed driving unit 27 may include, for example, any motor such as a servo motor or a stepping motor.

The sequence control circuitry 29 controls the gradient magnetic field power supply 21, the transmission circuitry 23, and the reception circuitry 25 synchronously based on data collection conditions, subjects the subject P to data collection corresponding to the data collection conditions, and collects k-space data relating to the subject P. The data collection conditions define, for example, a pulse sequence, a magnitude of an electric current supplied from the gradient magnetic field power supply 21 to the gradient magnetic field coil 43, a timing of the supply of an electric current from the gradient magnetic field power supply 21 to the gradient magnetic field coil 43, a magnitude of an RF pulse supplied from the transmission circuitry 23 to the transmitter coil 45, a timing of the supply of an RF pulse from the transmission circuitry 23 to the transmitter coil 45, a timing of the reception of an MR signal at the receiver coil 47, etc.

As shown in FIG. 11, the host computer 50 is a computer that includes processing circuitry 10, a memory 53, a display 55, an input interface 57, and a communication interface 59.

The processing circuitry 10 is the same as the processing circuitry 10 shown in FIG. 1. That is, the processing circuitry 10 controls the sequence control circuitry 29, the transmitter coil 45, the gradient magnetic field coil 43, the receiver coil 47, etc., to collect k-space data under-sampled at each of a plurality of coils.

The memory 53 is a storage device such as a hard disk drive (HDD), solid state drive (SSD), or integrated circuit storage device for storing various kinds of information. The memory 53 may also be, for example, a driver that reads and writes various kinds of information from and in a portable storage medium such as a CD-ROM drive, DVD drive, or flash memory. For example, the memory 53 stores k-space data, a sparse reconstructed image, a full reconstructed image, a trained model, a control program, and the like.

The display 55 displays various kinds of information. For example, a CRT display, a liquid crystal display, an organic EL display, an LED display, a plasma display, or any other display known in the relevant technical field can be suitably used as the display 55.

The input interface 57 includes an input device that receives various commands from a user. Examples of the input device that can be used include a keyboard, a mouse, various switches, a touch screen, and a touch pad. The input device is not limited to those provided with physical operational components such as a mouse and a keyboard. Examples of the input interface 57 also include electric signal processing circuitry that receives an electric signal corresponding to an input operation from an external input device provided separately from the magnetic resonance imaging apparatus 2, and outputs the received electric signal to various types of circuitry. The input interface 57 may also be a voice recognition device that collects voice signals via a microphone and converts the voice signals into command signals.

The communication interface 59 is an interface that connects the magnetic resonance imaging apparatus 2 with a workstation, a picture archiving and communication system (PACS), a hospital information system (HIS), a radiology information system (RIS), etc., via a local area network (LAN), etc. The communication interface 59 transmits and receives various kinds of information to and from the connected workstation, PACS, HIS, and RIS.

According to the fourth embodiment described above, it is possible to enhance the image quality of MR images as in the first embodiment.

The term “processor” used in the above description means, for example, a CPU, a GPU, or circuitry such as an application specific integrated circuit (ASIC), a programmable logic device (e.g., a simple programmable logic device (SPLD), a complex programmable logic device (CPLD), or a field programmable gate array (FPGA)). The processor implements a function by reading and executing a program stored in storage circuitry. The program may be directly incorporated into the circuitry of the processor instead of being stored in the storage circuitry. In this case, the processor implements the function by reading and executing the program incorporated into the circuitry. The function corresponding to the program may be realized by a combination of logic circuits, not by executing the program. Each processor of the present embodiment is not limited to being configured as single circuitry; multiple sets of independent circuitry may be integrated into a single processor that implements its functions.

Furthermore, multiple components may be integrated into a single processor to implement the functions of the processor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A reconstruction apparatus comprising processing circuitry configured to:
generate one or more sparse reconstructed images by performing image reconstruction on k-space data collected at each of a plurality of coils through under-sampling;
generate a first sensitivity map corresponding to each coil of the plurality of coils by using a first trained model;
perform a data consistency process for improving a degree of coincidence of data relating to the one or more sparse reconstructed images by using the first sensitivity map; and
generate a full reconstructed image by performing a coil synthesis process using a second sensitivity map on the one or more sparse reconstructed images subjected to the data consistency process.

2. The reconstruction apparatus according to claim 1, wherein the second sensitivity map is generated based on the k-space data, prescan data obtained when the k-space data is acquired, or k-space data collected at a different timing from the k-space data and relating to main scanning.

3. The reconstruction apparatus according to claim 1, wherein the second sensitivity map is generated by inputting k-space data used at the processing circuitry to a second trained model, the second trained model being trained so as to input k-space data and output a sensitivity map.

4. The reconstruction apparatus according to claim 1, wherein the k-space data acquired through under-sampling is one of k-space data acquired by a half-Fourier method, randomly sampled k-space data, regularly sparsely-acquired k-space data, or k-space data in which low-frequency components are acquired.

5. The reconstruction apparatus according to claim 1, wherein if a number of the one or more sparse reconstructed images is one, the processing circuitry generates a plurality of sparse reconstructed images corresponding to the respective coils by using the first sensitivity map and performs the coil synthesis process on the generated plurality of sparse reconstructed images.

6. The reconstruction apparatus according to claim 1, wherein the processing circuitry uses a common second sensitivity map for the coil synthesis process in a process performed on data of a first echo in multi-echo imaging and a process performed on data of a second echo differing from the first echo.

7. The reconstruction apparatus according to claim 1, wherein the processing circuitry uses the first sensitivity map for the coil synthesis process in a process performed on data of an echo in multi-echo imaging, the first sensitivity map being generated by a process performed on data of another echo in multi-echo imaging.

8. A reconstruction method comprising:
generating one or more sparse reconstructed images by performing image reconstruction on k-space data collected at each of a plurality of coils through under-sampling;
generating a first sensitivity map corresponding to each coil of the plurality of coils by using a first trained model;
performing a data consistency process for improving a degree of coincidence of data relating to the one or more sparse reconstructed images by using the first sensitivity map; and
generating a full reconstructed image by performing a coil synthesis process using a second sensitivity map on the one or more sparse reconstructed images subjected to the data consistency process.

9. The reconstruction method according to claim 8, wherein the second sensitivity map is generated based on the k-space data, prescan data obtained when the k-space data is acquired, or k-space data collected at a different timing from the k-space data and relating to main scanning.

10. The reconstruction method according to claim 8, wherein the second sensitivity map is generated by inputting k-space data used at the processing circuitry to a second trained model, the second trained model being trained so as to input k-space data and output a sensitivity map.

11. The reconstruction method according to claim 8, wherein the k-space data acquired through under-sampling is one of k-space data acquired by a half-Fourier method, randomly sampled k-space data, regularly sparsely-acquired k-space data, or k-space data in which low-frequency components are acquired.

12. The reconstruction method according to claim 8, if a number of the one or more sparse reconstructed images is one, the method further comprising generating a plurality of sparse reconstructed images corresponding to the respective coils by using the first sensitivity map and performs the coil synthesis process on the generated plurality of sparse reconstructed images.

13. The reconstruction method according to claim 8, further comprising using a common second sensitivity map for the coil synthesis process in a process performed on data of a first echo in multi-echo imaging and a process performed on data of a second echo differing from the first echo.

14. The reconstruction method according to claim 8, further comprising using the first sensitivity map for the coil synthesis process in a process performed on data of an echo in multi-echo imaging, the first sensitivity map being generated by a process performed on data of another echo in multi-echo imaging.

15. A magnetic resonance imaging apparatus comprising:
a collection unit configured to collect k-space data for each of a plurality of coils, the k-space data being under-sampled at each of the plurality of coils; and
processing circuitry configured to:
generate one or more sparse reconstructed images by performing image reconstruction on k-space data collected at each of a plurality of coils through under-sampling;
generate a first sensitivity map corresponding to each coil of the plurality of coils by using a first trained model;
perform a data consistency process for improving a degree of coincidence of data relating to the one or more sparse reconstructed images by using the first sensitivity map; and
generate a full reconstructed image by performing a coil synthesis process using a second sensitivity map on the one or more sparse reconstructed images subjected to the data consistency process.
